(19) United States
(12) Patent Application Publication
(10) Pub. No.: US 2026/0059996 A1
(43) Pub. Date: Feb. 26, 2026

(54) METHOD OF CONTROLLING SURFACE SHAPE OF LIQUID LAYER AND APPARATUS FOR CONTROLLING SURFACE SHAPE OF LIQUID LAYER

(71) Applicant: SAMSUNG DISPLAY CO., LTD., YONGIN-SI (KR)

(72) Inventors: Jeong Ho YI, Yongin-si (KR); Lae Ho KIM, Yongin-si (KR); Yeong Jun KIM, Yongin-si (KR)

(21) Appl. No.: 19/066,833

(22) Filed: Feb. 28, 2025

(30) Foreign Application Priority Data
Aug. 23, 2024 (KR) 10-2024-0113404

(51) Int. Cl. H10K 71/13

(52) U.S. Cl. CPC H10K 71/135

(57) ABSTRACT

A method of controlling a surface shape of a liquid layer includes: disposing the liquid layer on a base; providing an electrode assembly at the periphery of the liquid layer; and controlling the surface shape of the liquid layer disposed on the base, using the electrode assembly.

### CROSS-REFERENCE TO RELATED APPLICATION

This application claims priority under 35 U.S.C. § 119 to Korean Patent Application No. 10-2024-0113404, filed in the Korean Intellectual Property Office on Aug. 23, 2024, the entire contents of which are herein incorporated by reference.

### BACKGROUND

### 1. Technical Field

The present disclosure generally relates to a method of controlling a surface shape of a liquid layer and an apparatus for controlling a surface shape of a liquid layer.

### 2. Discussion of Related Art

An electronic device such as a display device typically includes a plurality of layers. The plurality of layers may be manufactured using various process methods. For example, some layers applied to a display device may be manufactured using a deposition process, a solution process, or the like.

In a process of direct printing or inkjet printing of microscale light emitting material such as quantum dot material, the quality of printed material may be limited by nonuniformities in droplet formation, wetting, and drying during printing.

### SUMMARY

Embodiments provide a method of controlling a surface shape of a liquid layer and an apparatus for controlling a surface shape of a liquid layer, in which a shape or an interface of the liquid layer can be controlled.

Embodiments also provide a method of controlling a surface shape of a liquid layer and an apparatus for controlling a surface shape of a liquid layer, in which a layer manufactured using the liquid layer can have an intended structure.

Embodiments also provide a method of controlling a surface shape of a liquid layer and an apparatus for controlling a surface shape of a liquid layer, in which process convenience can be improved.

In accordance with an aspect of the present disclosure, there is provided a method of controlling a surface shape of a liquid layer, a method including: disposing the liquid layer on a base; providing an electrode assembly at the periphery of the liquid layer; and controlling the surface shape of the liquid layer disposed on the base, using the electrode assembly.

The disposing may include providing the liquid layer on the base, using an inkjet process or a jetting process.

The electrode assembly may include a first electrode and a second electrode. The controlling may include: supplying a first signal to the first electrode; and supplying a second signal to the second electrode.

The controlling may include forming, by the electrode assembly, an electric field, and moving the liquid layer by a dielectrophoresis (DEP) force imparted to the liquid layer by the electric field.

The controlling may include imparting movement to at least a portion of the liquid layer.

The controlling may include moving at least one of the electrode assembly or the base, along a horizontal direction.

The controlling may include forming, by the electrode assembly, an electric field while moving the electrode assembly along a horizontal direction.

The controlling may include selectively applying an electric field to a portion of the liquid layer by the electrode assembly.

The controlling may include applying, by the electrode assembly, electric fields having different intensities to different areas of the liquid layer.

After the controlling, the liquid layer may have a flat upper surface.

After the controlling, the liquid layer may have a non-uniform surface.

In accordance with another aspect of the present disclosure, there is provided a method of manufacturing a display device, the method comprising disposing an encapsulation layer as a liquid layer on a base comprising a light emitting element surrounded by a pixel defining layer, providing an electrode assembly at a periphery of the liquid layer, and controlling a surface shape of the liquid layer disposed on the base, using the electrode assembly.

The controlling of a surface shape of the liquid layer may include controlling the surface shape of the liquid layer to have a flat center portion and a thick edge portion disposed at an edge of the base.

In accordance with another aspect of the present disclosure, there is provided an apparatus for controlling a surface shape of a liquid layer, a method including an electrode assembly provided at a periphery of the liquid layer disposed on a base, the electrode assembly including a first electrode and a second electrode, which are spaced apart from each other, and a processor controlling to the first electrode and the second electrode to form an electric field applied to the liquid layer.

The first electrode and the second electrode may be disposed above the liquid layer.

The first electrode and the second electrode may extend in a thickness direction of the base. The first electrode may be disposed above the liquid layer, and the second electrode may be disposed under the base.

The first electrode may be disposed above the liquid layer, and the second electrode may be formed by at least a portion of the base.

The first electrode may be disposed above the liquid layer, and the second electrode may be disposed under the base. The first electrode and the second electrode may extend in a horizontal direction.

The first electrode may be disposed above the liquid layer, and the second electrode may be disposed under the base. The first electrode may extend in a horizontal direction, and the second electrode may extend in a thickness direction of the base.

The first electrode and the second electrode may be disposed under the base.

### BRIEF DESCRIPTION OF THE DRAWINGS

Illustrative, non-limiting embodiments will be more clearly understood from the following detailed description in conjunction with the accompanying drawings.

FIG. 1 and FIG. 2 are schematic sectional views illustrating a liquid layer and a base in accordance with an embodiment of the present disclosure.

FIG. 3 is a schematic sectional view illustrating a display device including a layer manufactured using the liquid layer in accordance with an embodiment of the present disclosure.

FIG. 4 is a flowchart illustrating a method of controlling a surface shape of a liquid layer in accordance with an embodiment of the present disclosure.

FIGS. 5 to 13 are schematic views illustrating process steps of a method in accordance with an embodiment of the present disclosure.

FIG. 14 is a schematic block diagram illustrating an electronic device including a display device in accordance with an embodiment.

FIG. 15 is a schematic diagram illustrating an example where the electronic device of FIG. 14 is implemented as a smartphone.

FIG. 16 is a schematic diagram illustrating an example where the electronic device of FIG. 14 is implemented as a tablet computer.

### DETAILED DESCRIPTION

Example embodiments will now be described more fully hereinafter with reference to the accompanying drawings; however, they may be embodied in different forms and should not be construed as limited to embodiments set forth herein. Rather, embodiments are provided so that this disclosure will be thorough and complete, and will fully convey the scope of the example embodiments to those skilled in the art.

In the drawing figures, dimensions may be exaggerated for clarity of illustration. It will be understood that when an element is referred to as being “between” two elements, it can be the only element between the two elements, or one or more intervening elements may also be present. Like reference numerals refer to like elements throughout.

Hereinafter, embodiments of the present disclosure will be described in detail with reference to the attached drawings. In the following description, parts required for understanding of operations in accordance with the present disclosure will be described, and explanation of the other parts may be omitted. Accordingly, the present disclosure is not limited to embodiments set forth herein. That is, embodiments may be provided so that the present disclosure will be thorough and complete, and will fully convey the technical spirit of the disclosure to those skilled in the art.

It will be understood that, although the terms “first”, “second”, etc. may be used herein to describe various elements, these elements should not be limited by these terms. These terms are only used to distinguish one element from another element. Thus, a “first” element discussed below could also be termed a “second” element without departing from the teachings of the present disclosure. As used herein, the singular forms are intended to include the plural forms as well, unless the context clearly indicates otherwise.

It will be further understood that the terms “includes” and/or “including”, when used in this specification, specify the presence of stated features, integers, steps, operations, elements, and/or components, but do not preclude the presence and/or addition of one or more other features, integers, steps, operations, elements, components, and/or groups thereof. Further, an expression that an element such as a layer, region, substrate or plate is placed “on” or “above” another element indicates not only a case where the element is placed “directly on” or “just above” the other element but also a case where a further element is interposed between the element and the other element. On the contrary, an expression that an element such as a layer, region, substrate or plate is placed “beneath” or “below” another element indicates not only a case where the element is placed “directly beneath” or “just below” the other element but also a case where a further element is interposed between the element and the other element.

The present disclosure generally relates to a method of controlling a surface shape of a liquid layer and an apparatus for controlling a surface shape of a liquid layer. A method of controlling a surface shape of a liquid layer may use a dielectrophoresis (DEP) force imparted by an electric field to control the surface shape of the liquid layer. For example, surface shape of a liquid layer may be controlled to have a flat surface or may be controlled to have a shape that reduces a risk of spread a liquid layer beyond a base layer when a display device is manufactured. Hereinafter, a method of controlling a surface shape of a liquid layer and an apparatus for controlling a surface shape of a liquid layer in accordance with an embodiment of the present disclosure will be described with reference to the accompanying drawings.

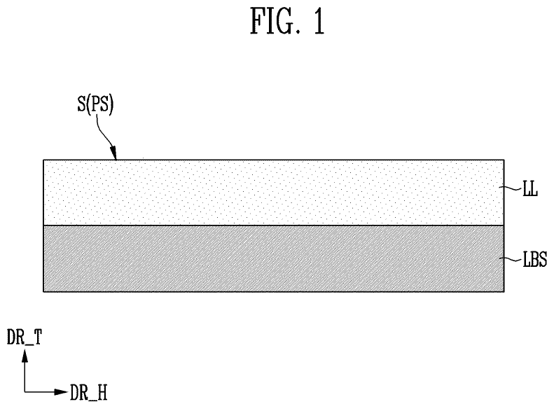

A liquid layer LL and a display device DD including a layer manufactured using the liquid layer LL will be described with reference to FIGS. 1 to 3.

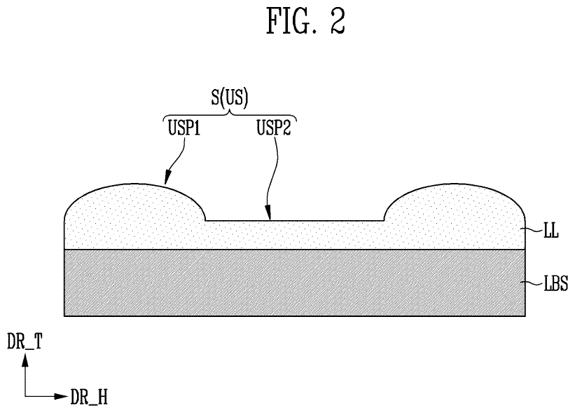

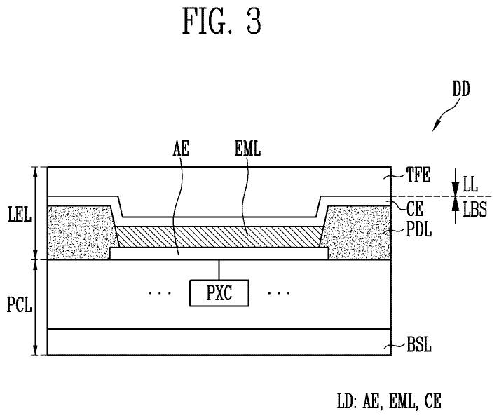

FIG. 1 and FIG. 2 are schematic sectional views illustrating a liquid layer and a base in accordance with an embodiment of the present disclosure. FIG. 3 is a schematic sectional view illustrating a display device including a layer manufactured using the liquid layer in accordance with an embodiment of the present disclosure.

In some embodiments, the liquid layer LL may be manufactured using a solution process. The solution process may be a process of manufacturing a layer (e.g., a thin film) by discharging, on a base LBS, a target material having a liquid phase, such as in an ink form.

The liquid layer LL may be provided on the base LBS, using various solution processes. For example, the liquid layer LL may be discharged (e.g., printed) on the base LBS, using an inkjet process or spin coating. Alternatively, the liquid layer LL may be disposed (e.g., jetted) on the base LBS, using a jetting process. However, the present disclosure is not necessarily limited to a specific example.

The liquid layer LL may include a material of a target layer to be manufactured. For example, when an encapsulation layer TFE is manufactured using the liquid layer, the liquid layer LL may include an inorganic material, which may be included in the encapsulation layer TFE. Alternatively, in some embodiments, the liquid layer LL may include an organic material.

In some embodiments, the liquid layer LL may be referred to as a liquid film.

The base LBS may form a base on which the liquid layer LL can be provided. The base LBS may be a substrate on which the liquid layer LL can be printed or jetted. For example, when the encapsulation layer TFE is manufactured using the liquid layer LL, the base LBS may be a light emitting element LD (or a cathode electrode CE) disposed under the encapsulation layer TFE. Alternatively, the base LBS may include all or some of the layers disposed under the encapsulation layer TFE. For example, the base LBS may include a base layer BSL and layers disposed between the base LBS and the encapsulation layer TFE. The base LBS may include the base layer BSL.

The liquid layer LL may include a liquid upper surface S (e.g., top surface). The liquid upper surface S may be a front surface of the liquid layer, which faces away from the base LBS. For example, the liquid layer LL may be disposed on the base LBS along a thickness direction DR_T of the base LBS, and the liquid upper surface S may face upward in the thickness direction DR_T.

The liquid upper surface S of the liquid layer LL may have an intended shape by a method of controlling a surface shape of the liquid layer LL in accordance with an embodiment of the present disclosure.

For example (see FIG. 1), the liquid upper surface S may be a flat surface PS. In some embodiments, the liquid upper surface S may be substantially flat, and may not include bending. The flat surface PS in accordance with an embodiment of the present disclosure may have a uniform structure intended by a method of controlling the surface shape of the liquid layer LL. For example, the flat surface PS in accordance with an embodiment of the present disclosure may not change as time elapses after the solution process of manufacturing the liquid layer LL.

Alternatively, for example (see FIG. 2), the liquid upper surface S may have a non-uniform surface US. In some embodiments, a portion of the liquid upper surface S may protrude as compared with at least another portion of the liquid upper surface S. For example, the non-uniform surface US may include a first portion USP1 and a second portion USP2. The first portion USP1 may protrude in the thickness direction DR_T as compared with the second portion USP2. The liquid layer LL may have a relatively thick thickness at the first portion USP1 when comparing the first portion USP1 with the second portion USP2.

The non-uniform surface US in accordance with an embodiment of the present disclosure may have a non-uniform structure intended by a method of controlling the surface shape of the liquid layer LL. For example, the non-uniform surface US in accordance with an embodiment of the present disclosure may have an expected shape generated by a solution process and a surface shape controlling process of manufacturing the liquid layer LL. For example, the liquid layer LL may have a flat surface having a relatively thin thickness at a center portion thereof and a protruding surface having a relatively thick thickness at an edge portion surrounding the flat surface. Thus, a risk that the liquid layer LL will spread to the outside on the base layer BSL when the display device DD is manufactured can be reduced. The liquid layer LL may have a relatively thick thickness at an edge thereof, and have a relatively uniform thickness inside the liquid layer LL at a center portion thereof. Accordingly, a risk that a portion of the liquid layer LL will have an excessively thin thickness can be reduced.

A display device DD to which a layer manufactured using the liquid layer LL is applied in accordance with an embodiment of the present disclosure will be described with reference to FIG. 3.

The display device DD may be configured to emit light. In some embodiments, the display device DD may include a pixel circuit layer PCL and a light emitting element layer LEL.

The pixel circuit layer PCL may include a base layer BSL. The pixel circuit layer PCL may be a layer including a pixel circuit PXC. The pixel circuit layer PCL may be a backplane layer. The pixel circuit PXC may be disposed on the base layer BSL, and be configured to drive a light emitting element LD. The pixel circuit layer PCL may include one or more conductive layers and one or more insulating layers. The conductive layers may form the pixel circuit PXC. The pixel circuit PXC may include circuit elements. The circuit elements may include a driving transistor, and include additional transistors and capacitors.

The light emitting element layer LEL may be disposed on the pixel circuit layer PCL. The light emitting element layer LEL may include the light emitting element LD. The light emitting element layer LEL may further include a pixel defining layer PDL and an encapsulation layer TFE.

The light emitting element LD may be electrically connected to the pixel circuit PXC. In some embodiments, the light emitting element LD may include various light sources. For example, the light emitting element LD may include an Organic Light Emitting Diode (OLED) including an organic material. However, the present disclosure is not necessarily limited thereto.

The light emitting element LD may include an anode electrode AE, a light emitting layer EML, and a cathode electrode CE. In some embodiments, the light emitting layer EML may be disposed in an area defined by the pixel defining layer PDL. The pixel defining layer PDL may be adjacent to the periphery of the light emitting layer EML. A surface of the light emitting layer EML may be electrically connected to the anode electrode AE, and the other surface of the light emitting layer EML may be electrically connected to the cathode electrode CE. The anode electrode AE and the cathode electrode CE may include various conductive materials.

The light emitting layer EML may include a plurality of layers. For example, the light emitting layer EML may include a hole transport unit, a light emitting unit (or light generation layer), and an electron transport unit. Each of layers forming the light emitting layer EML may include an organic light emitting material, and in some embodiments, may include a metal-containing compound, an inorganic light emitting material such as a quantum dot, or the like.

The pixel defining layer PDL may be disposed on the pixel circuit layer PCL. The pixel defining layer PDL may define a position at which the light emitting layer EML is arranged. The pixel defining layer PDL may include an organic material or an inorganic material. For example, the pixel defining layer PDL may include a plurality of layers each including an inorganic material. However, the present disclosure is not limited thereto.

The encapsulation layer TFE may be disposed over the light emitting element LD. For example, the encapsulation layer TFE may be disposed on the cathode electrode CE of the light emitting element LD. The encapsulation layer TFE may have a flat upper surface. The encapsulation layer TFE may fill a step difference caused by the light emitting element LD and the pixel defining layer PDL. The encapsulation layer TFE may include a plurality of insulating layers covering the light emitting element LD. In some embodiments, the encapsulation layer TFE may include an inorganic layer and an organic layer. For example, the encapsulation layer TFE may have a structure in which a first inorganic layer, an organic layer, and a second inorganic layer are sequentially disposed. However, the present disclosure is not limited thereto.

In some embodiments, the encapsulation layer TFE may be a thin film encapsulation layer. For example, the encapsulation layer TFE may be a thin film manufactured using the liquid layer LL. At least some of the plurality of layers forming the encapsulation layer TFE may be provided by the liquid layer LL. The cathode electrode CE, the base layer BSL, or the like may be the base LBS on which the liquid layer LL may be manufactured. As illustrated in FIG. 3, even when the cathode electrode CE includes a step difference, the surface shape of the liquid layer LL may be controlled, and the encapsulation layer TFE may be provided to have an intended surface shape.

The liquid layer LL may be used to manufacture various layers included in the display device DD in addition to the encapsulation layer TFE.

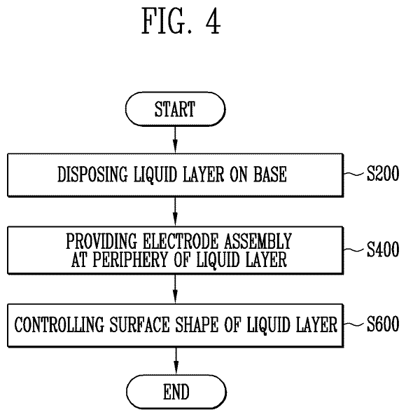

A method of controlling a surface shape of a liquid layer LL and an apparatus for controlling a surface shape of a liquid layer LL will be described with reference to FIGS. 4 to 13. For convenience of description, repetitive descriptions of portions described elsewhere herein may be simplified or omitted.

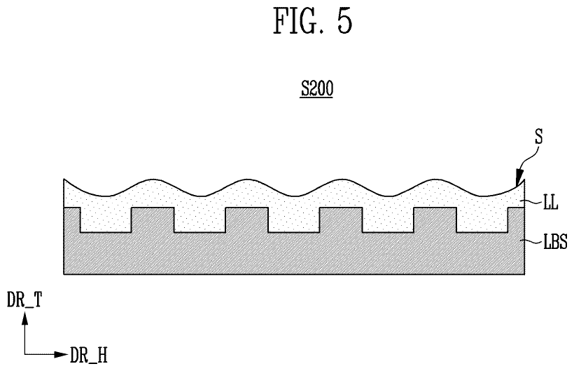

FIG. 4 is a flowchart illustrating a method of controlling a surface shape of a liquid layer in accordance with an embodiment of the present disclosure. FIGS. 5 to 13 are schematic views illustrating process steps of a method in accordance with an embodiment of the present disclosure. For convenience of description, in FIGS. 5 to 13, a structure is illustrated in which a base LBS has a non-uniform surface at a upper surface facing a liquid layer LL.

Referring to FIG. 4, a method may include step S200 of disposing a liquid layer on a base, step S400 of providing an electrode assembly at the periphery of the liquid layer, and step S600 of controlling a surface shape of the liquid layer.

Referring to FIG. 4 and FIG. 5, in step S200 of disposing the liquid layer on the base, a base LBS may be provided (e.g., prepared), and a liquid layer LL may be disposed on the base LBS, using various process methods.

In step S200, the base LBS may be various lower members on which the liquid layer is disposed. For example, as described above with reference to FIG. 3, when the liquid layer LL is the encapsulation layer TFE to be provided, the base LBS may be the cathode CE disposed under the encapsulation layer TFE or a layer including the cathode electrode CE.

In step S200, the liquid layer LL may be provided (e.g., disposed) on the base LBS, using various solution processes. For example, as described herein, the liquid layer LL may be provided using an inkjet process, a jetting process, or the like.

In some embodiments, the base LBS may have a non-uniform upper surface. Accordingly, in step S200, a liquid upper surface S of the liquid layer LL may have a non-uniform shape (e.g., a section).

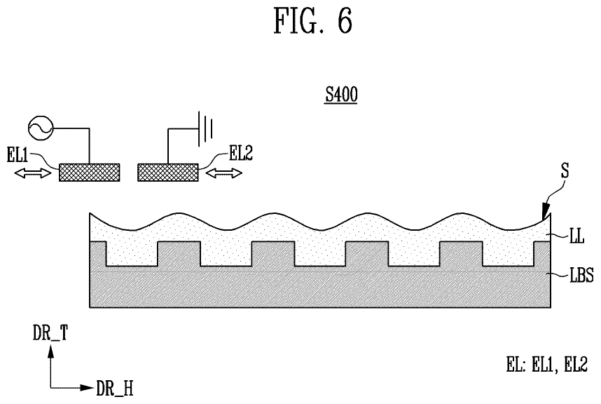

Referring to FIG. 4 and FIG. 6, in step S400 of providing the electrode assembly at the periphery of the liquid layer, an electrode assembly EL may be disposed adjacent to the liquid layer LL.

In some embodiments, the apparatus may include the electrode assembly EL.

The electrode assembly EL may be configured to form an electric field. The electrode assembly EL may include at least one electrode. For example, the electrode assembly EL may include a first electrode EL1 and a second electrode EL2.

The first electrode EL1 and the second electrode EL2 may be spaced apart from each other, and may be supplied with different electrical signals. The shape of the first electrode EL1 and the second electrode EL2 on a plane is not limited to a specific example. The first electrode EL1 may be supplied with a first signal, and the second electrode EL2 may be supplied with a second signal different from the first signal. The first signal and the second signal may have different waveforms, different potentials, and/or different phases. For example, the first signal may be an AC signal (or AC voltage), and the second signal may be a ground signal (or ground voltage). The AC signal may have a waveform such as a sine waveform, a cosine waveform, a sawtooth waveform, or a trapezoidal waveform. However, the present disclosure is not limited to the above-described example. For example, the first signal may be a DC signal and the second signal may be a ground signal.

Alternatively, in some embodiments, the second electrode EL2 is not applied with any separate electrical signal, but may form a ground potential. For example, at least a portion of the base LBS may form the ground potential without being applied with an electrical signal.

The electric field formed by the electrode assembly EL may induce movement (or flow) of the liquid layer LL. For example, the first electrode EL1 and the second electrode EL2 may be supplied with the first and second signals, respectively, and accordingly, an electric field may be formed in an area adjacent to the first electrode EL1 and the second electrode EL2. The formed electric field may be applied to the liquid layer LL, and at least a portion of the liquid layer LL may be moved by a force (e.g., a dielectrophoresis (DEP) force) according to the electric field. Typical frequencies for a DEP driven system are between about 100 Hz and about 10 MHz. In a DEP driven system the liquid layer LL may be subjected to a non-uniform electric field, which may create a dipole moment on particles of the liquid layer LL, that may cause the particles to be electrostatically pulled toward an electrode. For example, an electric field generated by the first electrode EL1 and the second electrode EL2 may be moved to a periphery of the liquid layer, within an effective distance of at least a portion of the liquid layer LL, and the portion of the liquid layer LL may be moved by the electric field to be concentrated on an area in which the electric field is applied. The effective distance of the electric field may be related to, for example, a power and a frequency of the electric field.

The electrode assembly EL may be moved relative to the liquid layer LL and the base LBS along a process direction. For example, the electrode assembly EL may be moved along a process direction, the base LBS may be moved opposite a process direction, or both the EL and LBS may be moved in opposite directions parallel to a process direction. For example, the electrode assembly EL may be moved in a horizontal direction DR_H. As the electrode assembly EL is moved in the horizontal direction DR_H, the electrode assembly EL may apply the electric field to each of various positions of the liquid upper surface S of the liquid layer LL.

In this specification, the horizontal direction DR_H may be a direction in which the liquid upper surface S extends and may be a direction in which a plane on which the base LBS extends. For example, the horizontal direction DR_H may be perpendicular to the thickness direction DR_T.

In some embodiments, the electrode assembly EL may be disposed on the liquid layer LL. The liquid layer LL may be disposed between the electrode assembly EL and the base LBS. For example, the first electrode EL1 and the second electrode EL2 may be disposed above the liquid layer LL. In some embodiments, the first electrode EL1 and the second electrode EL2 may extend in the horizontal direction DR_H, and be spaced apart from each other along the horizontal direction DR_H.

In some embodiments, the first electrode EL1 and the second electrode EL2 may include various conductive materials. For example, the first electrode EL1 and the second electrode EL2 may include at least one of gold (Au), silver (Ag), copper (Cu), aluminum (Al), or iron (Fe).

In step S400, the electrode assembly EL may be disposed above the liquid layer LL to be spaced apart from the liquid layer LL. The first electrode EL1 and the second electrode EL2 may be disposed above the liquid layer LL while being spaced apart from each other to face the liquid upper surface S.

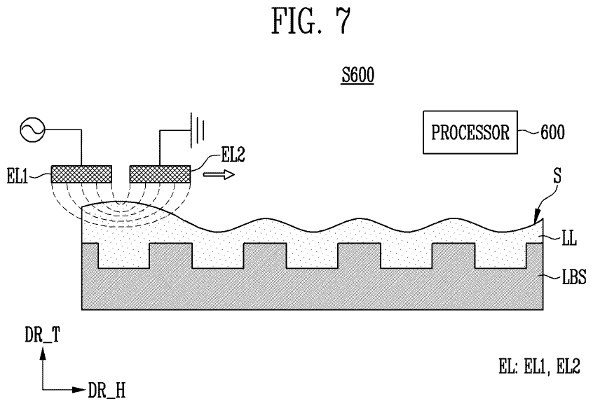

In some embodiments, before step S400 is performed, a step of inspecting whether a non-uniform shape such as an embossed stain exists on the liquid layer LL may be performed. For example, step S600 of controlling the surface shape of the liquid layer may be performed after it is checked whether an embossed stain exists in a step of the inspecting whether the non-uniform shape exists on the liquid layer LL is performed. In some embodiments, a processor 600 (see FIG. 7) may be provided. The processor 600 may perform a step of inspecting whether a non-uniform shape such as an embossed stain exists on the liquid layer LL may be performed. The processor 600 may perform step S600 of controlling the surface shape of the liquid layer.

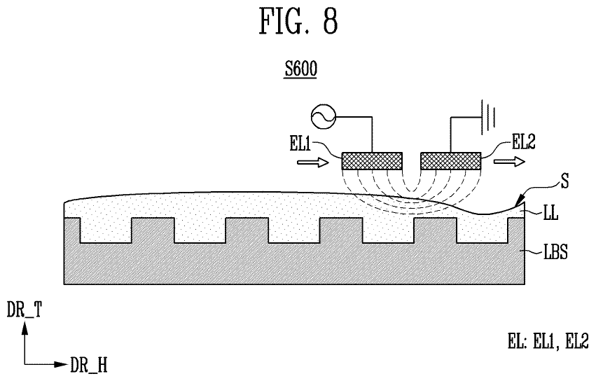

Referring to FIG. 4, FIG. 7, and FIG. 8, in step S600 of controlling the surface shape of the liquid layer, the electrode assembly EL may form an electric field to be applied to the liquid layer LL, thereby imparting movement (or flow) of the liquid layer LL.

In step S600, the electrode assembly EL may apply an electric field to the liquid layer LL, and the shape of at least a portion of the liquid layer LL to which the electric field is applied may be controlled. An application of the electric field by the electrode assembly EL may be controlled by the processor 600. A first signal may be supplied to the first electrode EL1, and a second signal may be supplied to the second electrode EL2. For example, the first signal may be, for example, an AC signal or a DC signal and the second signal may be a ground signal.

For example, the liquid layer LL may be provided in a solution form, and an electric field may be applied to the liquid layer LL. Accordingly, a portion of the electric field having a certain field gradient or a certain polarity may be imparted to at least a portion of the liquid layer LL, and at least a portion of the liquid layer LL may be moved according to a position at which the electric field is formed.

In step S600, the electric field may be pulsed or turned on/off at different positions about the liquid upper surface S. For example, at a partial process time, the electric field may be applied at a position at which the liquid upper surface S is formed at a low height, and the liquid layer LL may flow from an adjacent position having a relatively thick thickness. Accordingly, the liquid upper surface S of the liquid layer LL may be controlled to have a generally flat shape.

In step S600, the electrode assembly EL may be moved in the horizontal direction DR_H, and selectively apply an electric field to areas of the liquid upper surface S. Accordingly, the liquid upper surface S of the liquid layer LL may be controlled to have a generally flat shape. Movement of the electrode assembly EL and/or the base LBS may be controlled by the processor 600. For example, the base LBS may be loaded on a moveable stage, controlled by the processor 600.

In step S600, the electrode assembly EL may be moved in the horizontal direction DR_H while applying the electric field to the liquid layer LL. Accordingly, the electrode assembly EL may impart a flow of the liquid layer LL over an entirety of the liquid upper surface S, and the liquid upper surface S may be planarized. The liquid upper surface S in accordance with an embodiment of the present disclosure may have a uniform structure intended by a method of controlling the surface shape of the liquid layer LL. For example, the liquid upper surface S may be controlled to have a generally flat shape. For example, the generally flat shape may have a level height in the thickness direction DR-T or may have a convex shape over a surface of an entire surface the base LBS.

In step S600, although not shown in FIG. 8, the electrode assembly EL may locally apply an electric field to only a partial area of the liquid upper surface S of the liquid layer LL, and accordingly, the liquid layer LL may be manufactured to have a thicker thickness at an edge portion thereof. Alternatively, in some embodiments, the electrode assembly EL may apply electric fields having different intensities to different areas of the liquid upper surface S, and accordingly, the liquid layer LL may be manufactured to have a thicker thickness at an edge portion thereof. For example, the electrode assembly EL may change an intensity of an electric field at different areas of the liquid upper surface S according to a structure of the base LBS.

In a comparative process, when a solution process is performed, a formed layer may have an initially non-uniform interface shape (e.g., an embossed stain, or the like) due to fluidal characteristics of a provided solution.

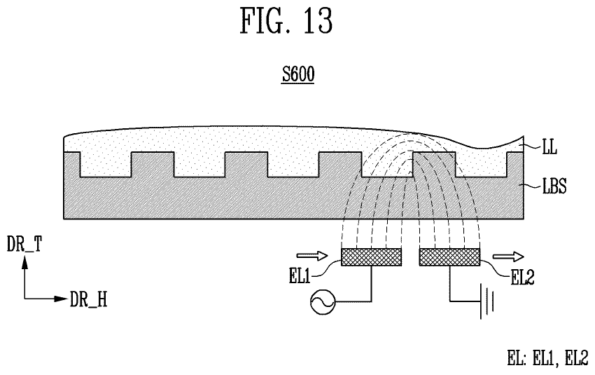

In accordance with an embodiment of the present disclosure, the surface shape of the liquid upper surface S of the liquid layer LL can be controlled using the electric field, and the liquid layer LL can be manufactured to have an intended interface shape (e.g., a flat shape). For example, the electric field may be used in a DEP process that may apply forces on materials of the liquid layer LL, which may be include a dielectric material. For example, a direction of a force applied by a DEP process may be dependent on field gradient and a direction of the force, or polarization, and may depend on the relative polarizabilities of particles, e.g., quantum dots, and a suspension medium (e.g., a solvent-free water-based suspension) of the liquid layer LL. If the particle moves in the direction of increasing electric field, the behavior may be referred to as positive DEP, if the particle moves in the direction of decreasing electric field, the behavior may be referred to as negative DEP. In a case that particles of the liquid layer LL have a positive DEP behavior, the liquid layer LL may be attracted to the electric field as shown in FIG. 7. In a case that particles of the liquid layer LL have a negative DEP behavior, the liquid layer LL may be repelled by the electric field as shown in FIG. 13. In either case, the surface shape of the liquid upper surface S of the liquid layer LL may be smoothed using the electric field.

In a comparative method, in order to reduce a risk that a formed layer may have an uneven surface after a solution process is performed, a process time for the formed layer may be extended. For example, the formed layer may be allowed to wait for a predetermined process time, e.g., a curing time of the formed layer, before any further processing may be performed.

In accordance with an embodiment of the present disclosure, as an active process method, the surface shape of the liquid upper surface S of the liquid layer LL can be controlled using the electric field, and a process time may be decreased. Accordingly, process convenience can be improved.

In a comparative method, as a solution process is performed, a phenomenon in which the liquid layer LL spreads toward an edge portion thereof may occur due to the fluidal characteristics of the liquid layer LL. For example, a thick edge portion may be formed adjacent to a thinned portion inward from the edge portion. In accordance with an embodiment of the present disclosure, as the electric field is applied to the edge portion of the liquid layer LL, the liquid layer LL can be manufactured to have a relatively consistent thickness at the edge portion thereof, and a risk that the liquid layer LL will excessively spread at an edge portion can be reduced.

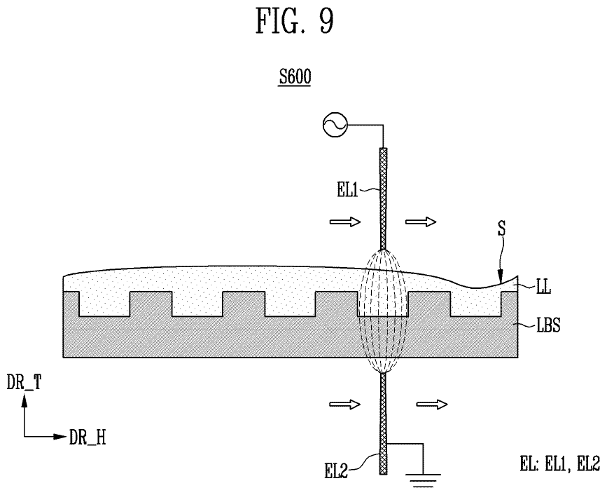

Various example structures of the electrode assembly EL will be described with reference to FIGS. 9 to 13. For convenience of description, FIGS. 9 to 13 illustrate the electrode assembly EL with respect to step S600. For convenience of description, repetitive descriptions of portions described elsewhere herein may be simplified or omitted.

Referring to FIG. 9, an electrode assembly EL in accordance with an embodiment of the present disclosure may include a first electrode EL1 and a second electrode EL2, which may extend in the thickness direction DR_T.

In some embodiments, the first electrode EL1 and the second electrode EL2 may extend in the thickness direction DR_T, and accordingly, an end portion of each of the first electrode EL1 and the second electrode EL2, which form an electric field, may have a relatively narrow width.

The first electrode EL1 and the second electrode EL2 may be spaced apart from each other in the thickness direction DR_T. For example, the first electrode EL1 may be disposed above the liquid layer LL and the second electrode EL2 may be disposed under the base LBS. Accordingly, the base LBS and the liquid layer LL may be interposed between the first electrode EL1 and the second electrode EL2.

In accordance with an embodiment of the present disclosure, the first electrode EL1 and the second electrode EL2 can form the electric field in a relatively narrow area, and thus the surface shape of the liquid upper surface S of the liquid layer LL can be more thoroughly controlled.

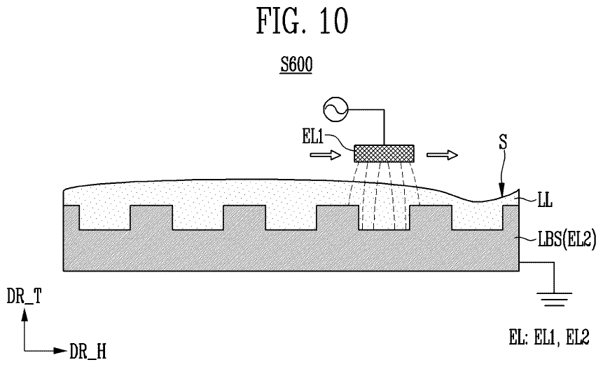

Referring to FIG. 10, a second electrode EL2 in accordance with an embodiment of the present disclosure may be formed by at least a portion of the base LBS.

In some embodiments, a first electrode EL1 may be disposed above the liquid layer LL, and the second electrode EL2 to which a ground voltage or the like is supplied may be formed by at least a portion of the base LBS. For example, in conjunction with FIG. 3, the second electrode EL2 may be the anode electrode AE, and may be at least one conductive layer formed in the pixel circuit layer PCL. Meanwhile, in some embodiments, when the second electrode EL2 is a conductive structure relatively adjacent to the liquid layer LL, such as the cathode electrode CE, other layers may not be excessively interposed between the cathode electrode CE or the like, which may serve as the second electrode EL2, and a formed electric field can be thoroughly controlled, and thus the surface shape of the liquid upper surface S of the liquid layer LL can be more thoroughly controlled.

Alternatively, in some embodiments, an electric field may be formed between the first electrode EL1 and the base LBS, as the base LBS may be used to have a ground potential. In conjunction with FIG. 3, the second electrode EL2 may be the base layer BSL. The second electrode EL2 may include all layers between the base layer BSL and the encapsulation layer TFE.

In accordance with an embodiment of the present disclosure, any conductive member for forming the second electrode EL2 is not used, and thus process cost can be reduced.

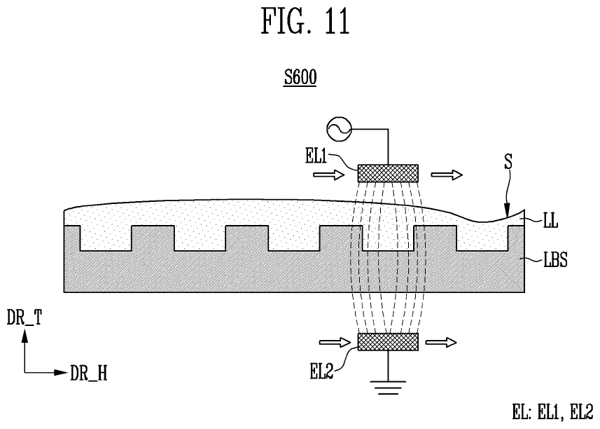

Referring to FIG. 11, a first electrode EL1 and a second electrode EL2 may extend in the horizontal direction DR_H. The first electrode EL1 may be disposed above the liquid layer LL, and the second electrode EL2 may be disposed under the base LBS.

In accordance with an embodiment, the base LBS and the liquid layer LL may be interposed between the first electrode EL1 and the second electrode EL2, and an electric field formed by the first electrode EL1 and the second electrode EL2 may be applied to the liquid layer LL.

In accordance with an embodiment of the present disclosure, since an electric field is formed between the first electrode EL1 and the second electrode EL2 with the liquid layer LL interposed therebetween, the electric field can be more thoroughly applied to the liquid layer LL along the thickness direction DR_T.

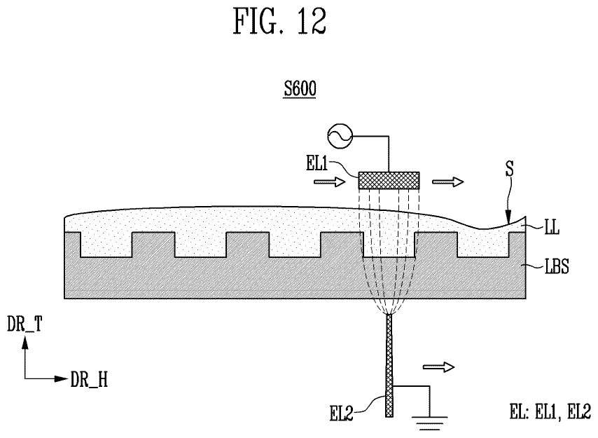

Referring to FIG. 12, a first electrode EL1 and a second electrode EL2 in accordance with an embodiment of the present disclosure may have different shapes.

In some embodiments, the first electrode EL1 may be disposed above the liquid layer LL, and extend in the horizontal direction DR_H. The second electrode EL2 may be disposed under the base LBS, and extend in the thickness direction DR_T.

In accordance with an embodiment of the present disclosure, an electric field can be formed between an end portion of the second electrode EL2 having a relatively narrow width and the first electrode EL1 having a relatively wide width. Accordingly, the electric field can be formed relatively widely at the liquid upper surface S of the liquid layer LL.

Referring to FIG. 13, a first electrode EL1 and a second electrode EL2 in accordance with an embodiment of the present disclosure may be disposed under the base LBS.

In some embodiments, the first electrode EL1 and the second electrode EL2 may not be disposed above the liquid layer LL, and may extend in a direction under the base LBS. The first electrode EL1 and the second electrode EL2 may form an electric field under the base LBS.

In accordance with an embodiment of the present disclosure, the first electrode EL1 and the second electrode EL2 may not be disposed above the liquid layer LL, and thus the arrangement freedom degree of process facilities can be improved.

Hereinafter, an electronic device 1000 including the display device DD in accordance with an embodiment will be described.

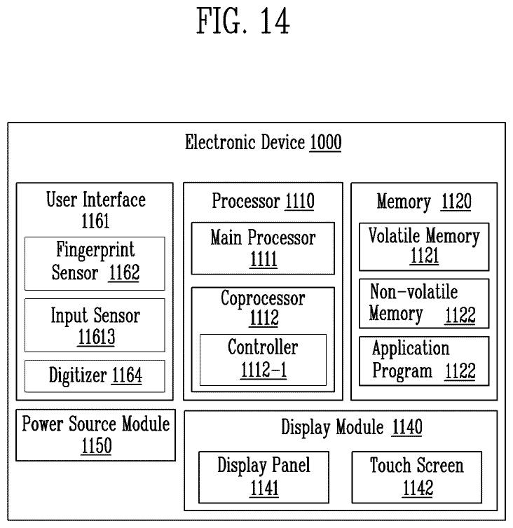

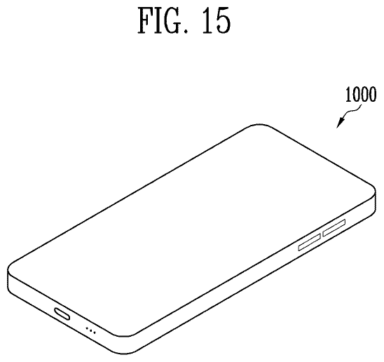

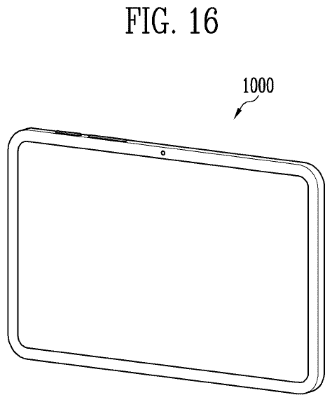

FIG. 14 is a schematic block diagram illustrating an electronic device 1000 including a display device in accordance with an embodiment. FIG. 15 is a schematic diagram illustrating an example where the electronic device 1000 of FIG. 14 is implemented as a smartphone. FIG. 16 is a schematic diagram illustrating an example where the electronic device 1000 of FIG. 14 is implemented as a tablet computer.

Referring to FIG. 14, FIG. 15, and FIG. 16, FIG. 14 is a diagram illustrating an electronic device according to an embodiment of the present invention. Referring to FIG. 14, the electronic device 1000 according to one embodiment of the present invention may output various information (e.g., images, text, music, etc.) through a display module 1140, which, for example, may correspond to the display device DD shown in FIG. 3. When a processor 1110 executes an application stored in a memory 1120, the display module 1140 may provide application information to a user through a display panel 1141.

In some embodiments, the electronic device 1000 may be configured as a smartphone, camera, smart TV, monitor, smartwatch, tablet, automotive display, or AR/VR headset. For example, the electronic device 1000 may be a smartphone including a touch-sensitive display area DA for interaction and a non-display area NDA including sensors and circuits for enhanced functionality. For example, the electronic device 1000 may be a television or monitor including a large display area DA for high-resolution video playback and a non-display area NDA incorporating driving circuits or connectivity modules for external inputs. For example, the electronic device 1000 may be a smartwatch including a display area DA optimized for compact and high-clarity visuals and a non-display area NDA integrating biometric sensors for health monitoring. In some cases, the electronic device 1000 be an AR/VR headset.

In some embodiments, memory 1120 may store information such as software codes for operating an application program 1123. The application program 1123 may include a software designed to execute specific tasks or provide functionality to a user. The application program 1123 may operate under the control of the processor 1110 and utilizes data stored in the memory 1120 to deliver a wide range of features, such as productivity tools, multimedia streaming and playback, file or mail deliveries or communication services. The application program 1123 interacts seamlessly with the user interface 1161 or touch screen 1142, allowing a user to launch, navigate, and utilize the program through user inputs such as touch, tap, gesture, or voice interaction.

Upon user selection of an application via touch screen 1142 or user interface 1161, the processor 1110 may execute the application program 1123 corresponding to the selected application retrieved from the memory 1120 to perform functionalities of the application. For example, when a user selects a camera application by tapping the icon (or a camera application icon) presented on the display panel 1141, the processor 1110 activates a camera module. The processor 1110 may transmit image data corresponding to a captured image acquired through the camera module to the display module 1140. The display module 1140 may display an image corresponding to the captured image through the display panel 1141.

As another example, when a user wishes to make a phone call, the user taps the telephone icon displayed on the display module 1140, the processor 1110 may execute a phone application program stored in the memory 1120. A telephone keypad may be presented on the display panel 1141 for the user to enter a phone number to call.

As another example, the display module 1140 may be integrated into an electronic device 1000, such as a laptop computer, smart TV, or tablet. A user wishing to access a multimedia streaming application (e.g., to watch a music video or movie) can do so by tapping the corresponding icon. This action activates the application, allowing the user to view the streamed content.

The processor 1110 may include a main processor 1111 and an auxiliary or coprocessor 1112. The main processor 1111 may include a central processing unit (CPU). The main processor 1111 may further include one or more of a graphics processing unit (GPU), a communication processor (CP), and an image signal processor (ISP).

The coprocessor 1112 may include a controller 1112-1. The controller 1112-1 may include an interface conversion circuit and a timing control circuit. The controller 1112-1 may receive an image signal from the main processor 1111, convert the data format of the image signal to match the interface specifications with the display module 1140, and output image data. The controller 1112-1 may output various control signals to drive the display module 1140. For example, the controller 1112-1 may drive the display module 1140 to display the icon on the display screen suitable for selection by a user to cause execution of an application program 1123.

The memory 1120 may store one or more application programs 1123 and various data used by at least one component (for example, the processor 1110 or the user interface 1161) of the electronic device 1000 and input data or output data for commands related thereto. For example, a camera application program, a GPS application program, an augmented reality and virtual reality application program, and other application programs that can be executed by the processor 1110 upon selection of corresponding icons presented on the display screen (or display panel 1141) via the touch screen 1142 or user interface 1161 by the user. In addition, various setting data corresponding to user settings may be stored in the memory 1120. The memory 1120 may include volatile memory 1121 and non-volatile memory 1122.

The display module 1140 may output visual information (images) to the user. The display module 1140 may include the display panel 1141, a gate driver, the source driver, a voltage generation circuit, and a touch screen 1142. The display module 1140 may further include a window, a chassis, and a bracket to protect the display panel 1141. The display module 1140 may include at least a part of the configuration of the display device DD shown in FIG. 3.

The user interface 1161 serves as the interaction medium between a user and the electronic device 1000. The user interface 1161 may detect an input by a part (e.g., finger) of a user's body or an input by a pen or a mouse, and generate an electric signal or data value corresponding to the input. The user interface 1161 includes the fingerprint sensor 1162, the input sensor 1163, and a digitizer 1164.

The fingerprint sensor 1162 may sense a fingerprint for biometric recognition of the user and may also measure one or more biological signals such as blood pressure, moisture, or body mass.

The input sensor 1163 may sense user interactions including touch, tap, gesture, motion, spoken command, and eye movement. The input sensor 1163 includes optical sensors for image capture, eye tracking, or motion and gesture detection. Optical sensors may be infrared or semiconductor photodetectors. The input sensor 1163 includes audio and acoustic sensors, which may be MEMS microphones for voice recognition or sound-based interaction. The audio and acoustic sensors can be installed as part of the user interface 1161 or embedded in the display panel 1141.

The digitizer 1164 may generate a data value corresponding to coordinate information of input by a pen or a mouse to control movement of an onscreen cursor. The digitizer 1164 may generate the amount of change in electromagnetic due to the input as the data value. The digitizer may detect an input by a passive pen or transmit and receive data with an active pen or a remote.

At least one of the fingerprint sensor 1162, the input sensor 1163, or the digitizer 1164 may be implemented as a sensor layer formed on the top layer of the display panel 1141 through a continuous process with a process of forming elements (for example, the light emitting element, the transistor, and the like) included in the display panel 1141.

In addition, the user interface 1161 may further include, for example, a gesture sensor, a gyro sensor that senses rotational movements, an acceleration sensor to track translational movement, a grip sensor, a pressure sensor, a proximity sensor, a color sensor, an infrared (IR) emitter and camera sensor for tracking gaze direction and eye movements, a temperature sensor, or a light sensor. For example, the gyro sensor, acceleration sensor, and infrared emitter and camera may be particularly suitable for AR/VR headset functions.

The touch screen 1142 includes touch sensors embedded in semiconductor layers of the display panel 1141 to sense pressure applied to the top layer (screen) of the display panel 1141. The touch sensors can be a capacitive or a resistive type. The touch screen 1142 may serve as the primary interface for the user to select and navigate applications, control, and interact with the electronic device 1000.

The display panel 1141 (or display) may include a liquid crystal display panel, an organic light emitting display panel, or an inorganic light emitting display panel, and the type of the display panel 1141 is not particularly limited. The display panel 1141 may be of a rigid type or a flexible type that can be rolled or folded. The display module 1140 may further include a supporter, bracket, heat dissipation member, and the like that support the display panel 1141. The display panel 1141 may include the display device DD shown in FIG. 3.

The power source module 1150 may supply power to the components of the electronic device 1000. The power source module 1150 may include a battery that charges the power source voltage. The battery may include a non-rechargeable primary battery or a rechargeable secondary battery or fuel cell. The power source module 1150 may include a power management integrated circuit (PMIC). The PMIC may supply optimized power source to each of the components described above including the display module 1140. In accordance with the present disclosure, there can be provided a method of controlling a surface shape of a liquid layer and an apparatus for controlling a surface shape of a liquid layer, in which a shape, an interface, and the like of the liquid layer can be thoroughly controlled.

In accordance with the present disclosure, there can be provided a method of controlling a surface shape of a liquid layer and an apparatus for controlling a surface shape of a liquid layer, in which a layer manufactured using the liquid layer can have an intended structure.

In accordance with the present disclosure, there can be provided a method of controlling a surface shape of a liquid layer and an apparatus for controlling a surface shape of a liquid layer, in which process convenience can be improved.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present disclosure as set forth in the following claims.

What is claimed is:

1. A method of controlling a surface shape of a liquid layer, the method comprising:
disposing the liquid layer on a base;
providing an electrode assembly at a periphery of the liquid layer; and
controlling the surface shape of the liquid layer disposed on the base, using the electrode assembly.

2. The method of claim 1, wherein the disposing includes providing the liquid layer on the base, using an inkjet process or a jetting process.

3. The method of claim 1, wherein the electrode assembly includes a first electrode and a second electrode, and
wherein the controlling includes:
supplying a first signal to the first electrode; and
supplying a second signal to the second electrode.

4. The method of claim 1, wherein the controlling comprises:
forming, by the electrode assembly, an electric field; and
moving the liquid layer by a dielectrophoresis (DEP) force imparted to the liquid layer by the electric field.

5. The method of claim 4, wherein the controlling includes imparting movement to at least a portion of the liquid layer.

6. The method of claim 4, wherein the controlling includes moving at least one of the electrode assembly or the base along a horizontal direction.

7. The method of claim 4, wherein the controlling includes forming, by the electrode assembly, an electric field while moving the electrode assembly along a horizontal direction.

8. The method of claim 4, wherein the controlling includes selectively applying an electric field to a portion of the liquid layer by the electrode assembly.

9. The method of claim 4, wherein the controlling includes applying, by the electrode assembly, electric fields having different intensities to different areas of the liquid layer.

10. The method of claim 1, wherein, after the controlling, the liquid layer has a flat upper surface.

11. The method of claim 1, wherein, after the controlling, the liquid layer has a non-uniform surface.

12. A method of manufacturing a display device, the method comprising:
disposing an encapsulation layer as a liquid layer on a base comprising a light emitting element surrounded by a pixel defining layer;
providing an electrode assembly at a periphery of the liquid layer; and
controlling a surface shape of the liquid layer disposed on the base, using the electrode assembly.

13. The method of claim 12, wherein controlling a surface shape of the liquid layer comprises controlling the surface shape of the liquid layer to have a flat center portion and a thick edge portion disposed at an edge of the base.

14. An apparatus for controlling a surface shape of a liquid layer, the apparatus comprising:
an electrode assembly provided at a periphery of the liquid layer disposed on a base, the electrode assembly including a first electrode and a second electrode, which are spaced apart from each other; and
a processor controlling to the first electrode and the second electrode to form an electric field applied to the liquid layer.

15. The apparatus of claim 14, wherein the first electrode and the second electrode are disposed above the liquid layer.

16. The apparatus of claim 14, wherein the first electrode and the second electrode extend in a thickness direction of the base, and
wherein the first electrode is disposed above the liquid layer, and
the second electrode is disposed under the base.

17. The apparatus of claim 14, wherein the first electrode is disposed above the liquid layer, and
the second electrode is formed by at least a portion of the base.

18. The apparatus of claim 14, wherein the first electrode is disposed above the liquid layer, and
the second electrode is disposed under the base, and
wherein the first electrode and the second electrode extend in a horizontal direction.

19. The apparatus of claim 14, wherein the first electrode is disposed above the liquid layer, and
the second electrode is disposed under the base, and
wherein the first electrode extends in a horizontal direction, and
the second electrode extends in a thickness direction of the base.

20. The apparatus of claim 14, wherein the first electrode and the second electrode are disposed under the base.
